(19) United States
(12) Patent Application Publication
(10) Pub. No.: US 2025/0105042 A1
(43) Pub. Date: Mar. 27, 2025

(54) Transport Vehicle

(71) Applicant: Daifuku Co., Ltd., Osaka-shi (JP)

(72) Inventor: Tadashi Nishikawa, Hinocho (JP)

(21) Appl. No.: 18/895,551

(22) Filed: Sep. 25, 2024

(30) Foreign Application Priority Data
Sep. 26, 2023 (JP) 2023-162864

(51) Int. Cl. H01L 21/677; B66C 13/22; B66C 19/00; H02P 23/14

(52) U.S. Cl. CPC H01L 21/6773; B66C 13/22; B66C 19/00; H02P 23/14; H01L 21/67733

(57) ABSTRACT

A transport vehicle transports an article. The transport vehicle includes a traveler including a traveler driver, a controller that controls the traveler, and a power supply unit that receives power from an external source and supplies the power at least to the traveler and the controller. The controller monitors a target voltage applied by the power supply unit to the traveler. The controller performs, during travel of the transport vehicle, a deceleration and stop process of decreasing a travel speed of the transport vehicle to stop the travel of the transport vehicle in response to the target voltage being lower than or equal to a determination threshold. The determination threshold is lower than a voltage of the power supply unit in normal operation and higher than a lower limit voltage. The lower limit voltage is a minimum voltage to cause the traveler to operate.

### CROSS-REFERENCE TO RELATED APPLICATION

This application claims priority to Japanese Patent Application No. 2023-162864 filed Sep. 26, 2023, the disclosure of which is hereby incorporated by reference in its entirety.

### BACKGROUND OF THE INVENTION

### Field of the Invention

The present invention relates to a transport vehicle that transports an article.

### Description of Related Art

For example, Japanese Unexamined Patent Application Publication No. 2022-003858 describes a technique for a transport vehicle. Reference signs in parentheses used hereafter in describing the background are the reference signs in Japanese Unexamined Patent Application Publication No. 2022-003858.

A transport facility (100) in Japanese Unexamined Patent Application Publication No. 2022-003858 includes a travel rail (2) along a travel path (1) and a transport vehicle (article transport vehicle 3) that travels along the travel path (1) while being guided by the travel rail (2). The transport facility (100) also includes a feed line (11) along the travel path (1) and multiple article processors (P). The transport vehicle receives driving power contactlessly from the feed line (11) to travel on the travel path (1) and transports an article to the article processors (P).

In the transport facility as in Japanese Unexamined Patent Application Publication No. 2022-003858, when no power is supplied to the feed line due to, for example, a power outage or a trouble in the power supply unit, the transport vehicle receives insufficient power for traveling and may stop suddenly on the travel rail. When the transport vehicle stops suddenly as above, the transport vehicle is likely to receive a larger load, with a larger acceleration on the article being transported. The transport vehicle may thus have a shorter service life, or the article being transported is likely to be damaged.

### SUMMARY OF THE INVENTION

One or more aspects are directed to a transport vehicle that can stop properly in response to a power supply failure.

A transport vehicle according to an aspect of the disclosure is a transport vehicle for transporting an article. The transport vehicle includes a traveler including a traveler driver, a controller that controls the traveler, and a power supply unit that receives power from an external source and supplies the power at least to the traveler and the controller. The controller monitors a target voltage applied by the power supply unit to the traveler. The controller performs, during travel of the transport vehicle, a deceleration and stop process of decreasing a travel speed of the transport vehicle to stop the travel of the transport vehicle in response to the target voltage being lower than or equal to a determination threshold. The determination threshold is lower than a voltage of the power supply unit in normal operation and higher than a lower limit voltage. The lower limit voltage is a minimum voltage to cause the traveler to operate.

In this structure, when a power supply failure due to, for example, a power outage or a trouble in the power supply unit causes a drop in the voltage (target voltage) applied to the traveler below the lower limit voltage, the transport vehicle can start decelerating in response to the voltage reaching the determination threshold. This structure can thus avoid a sudden stop of the transport vehicle with the traveler inoperable due to the target voltage lower than the lower limit voltage.

In this manner, the structure can avoid a sudden stop of the transport vehicle, reducing adverse effects such as a larger acceleration on the article being transported.

Further aspects and advantages of the transport vehicle will be apparent from exemplary and nonlimiting embodiments described below with reference to the drawings.

### BRIEF DESCRIPTION OF THE DRAWINGS

The terms Fig., Figs., Figure, and Figures are used interchangeably in the specification to refer to the corresponding figures in the drawings.

FIG. 1 is a schematic front view of a transport vehicle in a transfer operation.

FIG. 2 is a plan view of a travel path for the transport vehicle and processing devices.

FIG. 3 is a side view of the transport vehicle.

FIG. 4 is a control block diagram.

FIG. 5 is a diagram showing a stop pattern of the transport vehicle in a deceleration and stop process.

FIG. 6 is a control flowchart.

FIG. 7 is a control flowchart.

FIG. 8 is a control flowchart.

FIG. 9 is a control flowchart in another embodiment.

### DESCRIPTION OF THE INVENTION

An example transport vehicle according to an embodiment used in a transport facility will be described.

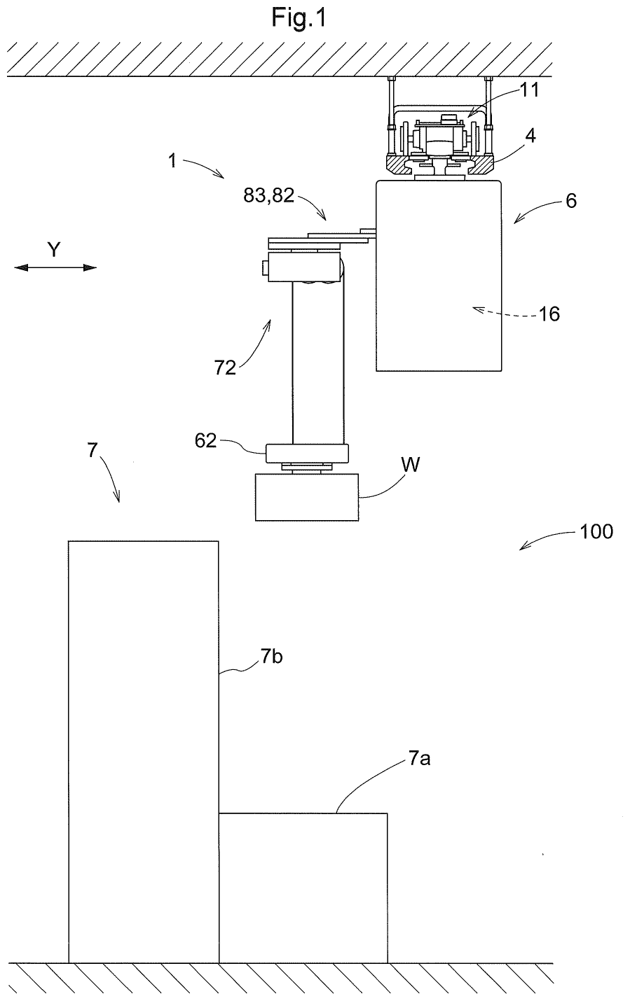

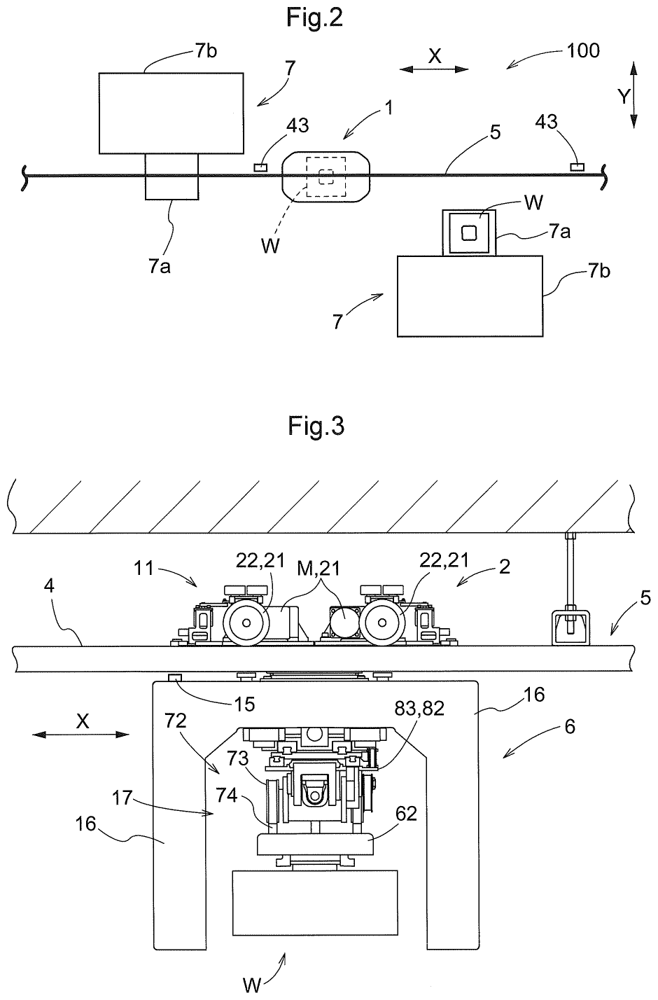

As shown in FIGS. 1 and 2, a transport facility 100 includes a transport vehicle 1 that travels along a travel path 5, travel rails 4 that guide the transport vehicle 1, multiple processing devices 7, and a host control system C that centrally controls the entire transport facility 100. The travel rails 4 extend along the travel path 5. The multiple processing devices 7 are arranged along the travel path 5.

In the present embodiment, the transport vehicle 1 transports articles W. More specifically, the transport vehicle 1 travels along the travel path 5 to transfer the articles W to the multiple processing devices 7. In the present embodiment, the travel path 5 extends along the ceiling of the transport facility 100. The travel rails 4 are thus hung from the ceiling. In other words, the transport vehicle 1 is a ceiling-hung transport vehicle that travels along the travel path 5 along the ceiling. The travel rails 4 are a pair of travel rails in this example. Multiple transport vehicles 1 travel on the pair of left and right travel rails 4 (FIG. 1). The transport vehicles 1 are not limited to the ceiling-hung transport vehicles. The transport vehicles 1 may be, for example, automated guided vehicles that autonomously travel on the floor or other surfaces.

The processing devices 7 perform a predetermined process on an article W. The multiple processing devices 7 are arranged below the travel rails 4. Each processing device 7 is disposed on the floor surface of the transport facility 100. In this example, the processing device 7 includes a transfer area 7a to which an article W is transferred and a processing body 7b in which the article W is processed. The transfer area 7a is a transfer port. In other words, the transfer area 7a is a port for transferring an article W to and from the transport vehicle 1. In the present embodiment, the article W may be, for example, a container for containing semiconductor wafers used for manufacturing a semiconductor device or reticles for processing. In other words, examples of the article W include a front-opening unified pod (FOUP) containing semiconductor wafers or a reticle pod containing reticles. The processing body 7b processes an object contained in the article W described above.

The host control system C transmits a transport command to each of the multiple transport vehicles 1 traveling on the travel path 5. Each transport vehicle 1 transports an article W between the multiple processing devices 7 based on the transport command from the host control system C. The host control system C includes a host communication device 101. The host communication device 101 communicates with a communication device 9 (described later) in each transport vehicle 1.

As shown in FIGS. 1 to 4, the transport vehicle 1 includes a traveler 2 that includes a traveler driver 21, a controller 10 that controls the traveler 2, and a power supply unit 3 that receives power from an external source and supplies the power at least to the traveler 2 and the controller 10. In the present embodiment, the transport vehicle 1 further includes a holder 62 that holds an article W, a lifter 72 that lifts and lowers the holder 62, a slider 82 that advances and retracts the holder 62 in a specific advancement and retraction direction Y parallel to the horizontal direction, and a communication device 9.

Hereafter, the direction parallel to the travel path 5 is referred to as a travel direction X, and the direction (rail width direction) perpendicular to the travel direction X as viewed from above is referred to as the advancement and retraction direction Y.

The traveler 2 includes, as the traveler driver 21, travel wheels 22 that roll on the travel rails 4 and a travel motor M that drives the travel wheels 22 (FIG. 3). In this example, as shown in FIGS. 1 and 3, the transport vehicle 1 further includes a body 11, a compartment 17 that accommodates an article W, and a cover 16 that covers the compartment 17. The body 11 includes multiple travel wheels 22 in this example. The travel motor M drives at least one of the multiple travel wheels 22 to provide a driving force for the body 11 to travel in the travel direction X. The travel motor M may be a linear motor. In this case, the travel wheels 22 may be eliminated. In this example, the body 11 is disposed above the travel rails 4.

The compartment 17 is defined below the travel rails 4. In the transport vehicle 1 transporting an article W toward the transfer area 7a, the body 11 travels with the article W accommodated in the compartment 17. The cover 16 is hung from the body 11. The cover 16 covers an upper portion of the compartment 17 and side portions of the compartment 17 in the travel direction X. In the example shown in the figure, side portions of the compartment 17 in the advancement and retraction direction Y are open without the cover 16.

The lifter 72 lifts and lowers the holder 62 between a height corresponding to the transfer area 7a and a height corresponding to the compartment 17. As shown in FIG. 3, the lifter 72 is disposed in the compartment 17. In this example, the lifter 72 includes a drum 73, a belt 74 wound around the drum 73 with a distal end connected to the holder 62, and a lifter motor (not shown). The lifter motor drives and rotates the drum 73 to wind or unwind the belt 74, lifting or lowering the holder 62 and the article W held by the holder 62. When the body 11 stops at a position corresponding to the transfer area 7a and the lifter 72 lifts and lowers the article W held by the holder 62, the article W can be transferred to and from the transfer area 7a (the transfer port in this example).

The slider 82 includes a sliding member 83 that moves in the advancement and retraction direction Y (the rail width direction in this example) relative to the compartment 17, and a slider motor (not shown) that slides the sliding member 83 in the advancement and retraction direction Y. When the slider motor drives and moves the sliding member 83, the lifter 72, the holder 62, and the article W held by the holder 62 move in the advancement and retraction direction Y. As shown in FIG. 2, for a processing device 7 with its transfer area 7a spaced from the travel path 5 in the advancement and retraction direction Y, the slider 82 slides the sliding member 83 to transfer the article W to and from the transfer area 7a. In this example, the slider 82 accommodated in the compartment 17 advances and retracts the sliding member 83 as appropriate in the advancement and retraction direction Y relative to the compartment 17.

The holder 62 includes a pair of holding tabs and a tab motor that moves the pair of holding tabs closer to and farther from each other. The holder 62 moves the pair of holding tabs closer to and farther from each other to switch them between a holding state for holding the article W and a releasing state for releasing the article W.

In this example, as shown in FIG. 3, the transport vehicle 1 includes a detector 15. The detector 15 detects multiple detectable members 43 (FIG. 2) arranged along the travel path 5. The detectable members 43 store positional information (address information) indicating the positions at which the detectable members 43 are arranged. The detector 15 reads the positional information. The detectable members 43 are arranged, for example, at positions corresponding to the transfer areas 7a, as well as at branching paths or joining paths in the travel path 5. The detectable members 43 are barcode labels and are attached on the lower surfaces of the rails of the travel rails 4 in this example. The detector 15 is attached to the upper surface of the cover 16 and reads barcode labels facing the cover 16 while the transport vehicle 1 is traveling.

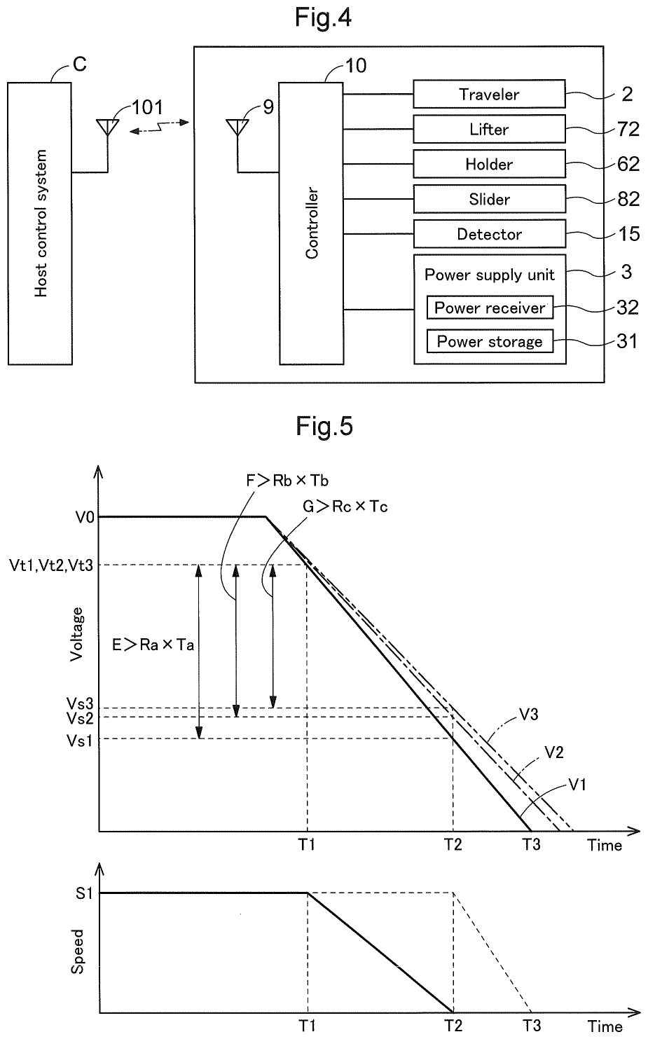

As shown in FIG. 4, the communication device 9 communicates with the host control system C that controls multiple transport vehicles 1. Examples of the functions of the communication device 9 include receiving a transport command from the host control system C and transmitting positional information, speed information, or other information about the transport vehicle 1 to the host control system C.

The power supply unit 3 includes a power receiver 32 (FIG. 4) that receives power from a feed line (not shown) extending along the travel path 5. In this example, the power receiver 32 receives power from the feed line contactlessly. The power receiver 32 includes a pickup coil (not shown) and a power receiving unit (not shown) formed on a wiring board inside the transport vehicle 1. The power receiving unit is electrically connected to the pickup coil. The power receiving unit is electrically connected to an electric load with variable power consumption. The alternating current and the alternating current voltage induced in the pickup coil are converted to a direct current and a direct current voltage in the power receiving unit through a power receiving circuit including a rectifier circuit, such as a full-wave rectifier circuit, and a smoothing capacitor, and then provided to the electric load. Examples of the electric load include the traveler 2, the holder 62, the lifter 72, and the slider 82 as described above.

In the present embodiment, as shown in FIG. 4, the power supply unit 3 includes a power storage 31 that temporarily stores power. The power storage 31 applies a voltage to the traveler 2. The power storage 31 is a device for responding to an instantaneous voltage drop in the transport vehicle 1 in this example. In other words, when a power supply failure due to, for example, a power outage or a trouble in the power supply unit 3 causes an instantaneous drop in the voltage applied to the traveler 2, the power storage 31 applies a voltage to the traveler 2. In the present embodiment, the power storage 31 can supply power to the electric loads such as the holder 62, the lifter 72, and the slider 82, as well as to the traveler 2. The power storage 31 may be a capacitor disposed on the board of the power supply unit 3. The power storage 31 may be a small battery.

As shown in FIG. 4, the controller 10 controls the traveler 2, the lifter 72, the holder 62, the slider 82, the detector 15, and the power supply unit 3. The controller 10 can communicate with the host control system C. The controller 10 and the host control system C each include, for example, a processor such as a microcomputer and peripheral circuitry including a memory. The functions of the components are implemented by the above hardware and a program executable on a processor such as a computer operating in cooperation with each other. In the present embodiment, the controller 10 controls the traveler 2 based on a command from the host control system C. The controller 10 also controls the holder 62 and the slider 82 based on a command from the host control system C. The controller 10 may control the traveler 2 alone.

Hereafter, a voltage applied by the power supply unit 3 to the traveler 2 is referred to as a first target voltage V1, and a minimum voltage to cause the traveler 2 to operate is referred to as a first lower limit voltage Vs1. A voltage applied by the power supply unit 3 to the lifter 72 is referred to as a second target voltage V2, and a minimum voltage to cause the lifter 72 to operate is referred to as a second lower limit voltage Vs2. Similarly, a voltage applied by the power supply unit 3 to the slider 82 is referred to as a third target voltage V3, and a minimum voltage to cause the slider 82 to operate is referred to as a third lower limit voltage Vs3. The first lower limit voltage Vs1 herein corresponds to the lower limit voltage.

As shown in FIG. 5, the controller 10 monitors the first target voltage V1. The controller 10 also monitors the second target voltage V2 and the third target voltage V3. In this example, the controller 10 monitors, as the first target voltage V1, the voltage applied to a driver (e.g., a servo driver; the same applies hereafter) included in the travel motor M in the traveler 2. The controller 10 monitors, as the second target voltage V2, the voltage applied to a driver included in the lifter motor. The controller 10 also monitors, as the third target voltage V3, the voltage applied to a driver included in the slider motor. The controller 10 may monitor the voltages applied to the bodies of the motors described above. The first target voltage V1 herein corresponds to the target voltage.

In the present embodiment, the controller 10 performs normal transportation control. The normal transportation control is to transport an article W between predetermined transfer areas 7a based on a transport command received from the host control system C. As an example of the normal transportation control, control of transporting an article W to a predetermined transfer area 7a will now be described. When receiving a transport command, the controller 10 controls the traveler 2 to move the transport vehicle 1 toward a position (a position on the travel rails 4 in this example) corresponding to a destination transfer area 7a. As the transport vehicle 1 approaches the position, the controller 10 controls the traveler 2 to decelerate and stop the transport vehicle 1 at an appropriate stop position. The controller 10 may decelerate the transport vehicle 1 when the detector 15 detects a detectable member 43 preceding the destination transfer area 7a. When the transport vehicle 1 stops, the controller 10 transmits information about the stop position to the host control system C. In this example, the controller 10 calculates the stop position based on the positional information obtained from the detectable member 43 and an amount of movement of the transport vehicle 1 from the detectable member 43 to the stop position detected by an encoder in the travel motor M.

For a destination transfer area 7a immediately below the travel rails 4, the controller 10 controls the lifter 72 to lower the holder 62 and the article W held by the holder 62. For a destination transfer area 7a at a position displaced from the travel rails 4 in the advancement and retraction direction Y, the controller 10 controls the slider 82 to move the holder 62 and the article W held by the holder 62 to a position immediately above the transfer area 7a. The controller 10 then controls the lifter 72 to lower the holder 62 and the article W held by the holder 62. After the article W is placed on the transfer area 7a, the controller 10 controls the holder 62 to cause the pair of holding tabs to be in the releasing state.

In the normal transportation control, a predetermined voltage that is set appropriately (normal voltage V0) is continuously applied to the traveler 2 while the transport vehicle 1 is traveling on the travel rails 4. When the transport vehicle 1 stops on the travel rail 4 to transfer the article W to the transfer area 7a, the normal voltage V0 is applied to the slider 82 and the lifter 72 as appropriate. In the example in FIG. 5, the same normal voltage V0 is applied to each of the traveler 2, the slider 82, and the lifter 72. Different normal voltages V0 may be applied to each of the traveler 2, the slider 82, and the lifter 72. The normal voltage V0 may be set with an upper limit value and a lower limit value, and the normal voltage V0 may range from the lower limit value to the upper limit value.

When no power is supplied to the power supply unit 3 due to, for example, a power outage, the first target voltage V1, the second target voltage V2, and the third target voltage V3 drop from the normal voltage V0 (FIG. 5). These target voltages may drop below the lower limit voltages (the first lower limit voltage Vs1, the second lower limit voltage Vs2, and the third lower limit voltage Vs3) when such a power supply failure causes, for example, insufficient power for the motors (the travel motor M, the lifter motor, and the slider motor) or errors in the drivers for the motors.

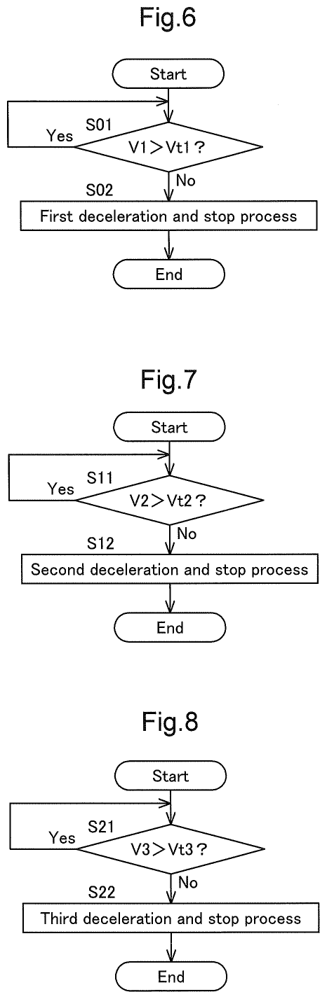

As shown in FIGS. 5 to 9, the controller 10 performs a first deceleration and stop process, a second deceleration and stop process, and a third deceleration and stop process. As shown in FIGS. 5 and 6, the first deceleration and stop process is performed during the travel of the transport vehicle 1. The process is to decrease the travel speed of the transport vehicle 1 to stop the travel of the transport vehicle 1 in response to the first target voltage V1 being lower than or equal to a first determination threshold Vt1. The first determination threshold Vt1 is lower than the voltage (normal voltage V0) of the power supply unit 3 in normal operation and higher than the first lower limit voltage Vs1. The first deceleration and stop process corresponds to the deceleration and stop process, and the first lower limit voltage Vs1 corresponds to the lower limit voltage in this example.

As shown in FIG. 5, the first determination threshold Vt1 is greater than or equal to a value obtained by adding the product of a first voltage drop rate Ra and a first processing time Ta to the first lower limit voltage Vs1, where the first processing time Ta is a time from the start to the completion of the first deceleration and stop process, and the first voltage drop rate Ra is a decrease in the first target voltage V1 per unit time resulting from abnormal power supply from the power supply unit 3. In the example in FIG. 5, the first voltage drop rate Ra from the normal voltage V0 is constant, but this is not limitative. In this example, a difference E between the first determination threshold Vt1 and the first lower limit voltage Vs1 is set to be greater than the product of the first voltage drop rate Ra and the first processing time Ta. The first determination threshold Vt1 is thus greater than a value obtained by adding the product of the first voltage drop rate Ra and the first processing time Ta to the first lower limit voltage Vs1. In this example, the first processing time Ta is a time from when the transport vehicle 1 starts decelerating to when the transport vehicle 1 stops moving in the travel direction X. The first voltage drop rate Ra corresponds to the voltage drop rate, and the first processing time Ta corresponds to the processing time.

In the present embodiment, as shown in FIG. 6, the controller 10 determines whether the first target voltage V1 is greater than the first determination threshold Vt1 (S01). When determining that the first target voltage V1 is less than or equal to the first determination threshold Vt1 (No in S01), the controller 10 performs the first deceleration and stop process (S02). In this example, when detecting that the first target voltage V1 is the same as the first determination threshold Vt1, the controller 10 controls the traveler 2 to decelerate the transport vehicle 1. The controller 10 controls the traveler 2 to stop the transport vehicle 1 before the first target voltage V1 drops below the first lower limit voltage Vs1. In the example in FIG. 5, the controller 10 stops the transport vehicle 1 in response to the first target voltage V1 being the same as the first lower limit voltage Vs1. In this manner, in the first deceleration and stop process, the controller 10 controls the traveler 2 to stop the transport vehicle 1 within a period in which the first target voltage V1 is less than the first determination threshold Vt1 and greater than or equal to the first lower limit voltage Vs1. In this example, the controller 10 decelerates the transport vehicle 1 at a predetermined deceleration rate and stops the transport vehicle 1 before the first target voltage V1 drops below the first lower limit voltage Vs1. In the example shown in the figure, the transport vehicle 1 has a constant deceleration rate per unit time, but this is not limitative. The controller 10 may transmit information about the stop position of the transport vehicle 1 to the host control system C after the first deceleration and stop process. This allows the host control system C to estimate the accurate stop position of the transport vehicle 1 more easily in a restoration operation after the power supply failure is removed. This shortens the time taken for the restoration operation. The controller 10 may not monitor the first target voltage V1. In this case, the controller 10 may not perform the first deceleration and stop process.

As shown in FIGS. 5 and 7, the second deceleration and stop process is performed during the holder 62 being lifted or lowered by the lifter 72. The process is to decrease the speed of the holder 62 being lifted or lowered by the lifter 72 to stop lifting or lowering of the holder 62 in response to the second target voltage V2 being lower than or equal to the second determination threshold Vt2. The second determination threshold Vt2 is lower than the voltage of the power supply unit 3 in normal operation and higher than the second lower limit voltage Vs2.

As shown in FIG. 5, the second determination threshold Vt2 is greater than or equal to a value obtained by adding the product of a second voltage drop rate Rb and a second processing time Tb to the second lower limit voltage Vs2, where the second processing time Tb is a time from the start to the completion of the second deceleration and stop process, and the second voltage drop rate Rb is a decrease in the second target voltage V2 per unit time resulting from abnormal power supply from the power supply unit 3. In the example in FIG. 5, the second voltage drop rate Rb from the normal voltage V0 is constant, but this is not limitative. In this example, a difference F between the second determination threshold Vt2 and the second lower limit voltage Vs2 is set to be greater than the product of the second voltage drop rate Rb and the second processing time Tb. The second determination threshold Vt2 is thus greater than a value obtained by adding the product of the second voltage drop rate Rb and the second processing time Tb to the second lower limit voltage Vs2. In this example, the second processing time Tb is a time from when the holder 62 starts decelerating (decreasing the lifting and lowering speed) to when the holder 62 stops.

In the present embodiment, as shown in FIG. 7, the controller 10 determines whether the second target voltage V2 is greater than the second determination threshold Vt2 (S11). When determining that the second target voltage V2 is less than or equal to the second determination threshold Vt2 (No in S11), the controller 10 performs the second deceleration and stop process (S12). In this example, when detecting that the second target voltage V2 is the same as the second determination threshold Vt2, the controller 10 controls the lifter 72 to decelerate the holder 62. The controller 10 controls the lifter 72 to stop lifting and lowering the holder 62 before the second target voltage V2 drops below the second lower limit voltage Vs2. In the example in FIG. 5, the controller 10 stops the holder 62 in response to the second target voltage V2 being the same as the second lower limit voltage Vs2. In this manner, in the second deceleration and stop process, the controller 10 controls the lifter 72 to stop the holder 62 within a period in which the second target voltage V2 is less than the second determination threshold Vt2 and greater than or equal to the second lower limit voltage Vs2. The controller 10 may transmit information about the stop position of the holder 62 in a vertical direction (lifting direction) to the host control system C after the second deceleration and stop process. This allows the host control system C to estimate the accurate stop position of the holder 62 more easily in a restoration operation after the power supply failure is removed. This shortens the time taken for the restoration operation. The controller 10 can estimate the position of the holder 62 in the vertical direction using, for example, an encoder mounted on the lifter motor.

As shown in FIGS. 5 and 8, the third deceleration and stop process is performed during the holder 62 being advanced or retracted by the slider 82. The process is to decrease the speed of the holder 62 being advanced or retracted by the slider 82 to stop advancing or retracting of the holder 62 in response to the third target voltage V3 being lower than or equal to the third determination threshold Vt3. The third determination threshold Vt3 is lower than the voltage (normal voltage V0) of the power supply unit 3 in normal operation and higher than the third lower limit voltage Vs3.

As shown in FIG. 5, the third determination threshold Vt3 is greater than or equal to a value obtained by adding the product of a third voltage drop rate Rc and a third processing time Tc to the third lower limit voltage Vs3, where the third processing time Tc is a time from the start to the completion of the third deceleration and stop process, and the third voltage drop rate Rc is a decrease in the third target voltage V3 per unit time resulting from abnormal power supply from the power supply unit 3. In the example in FIG. 5, the third voltage drop rate Rc from the normal voltage V0 is constant, but this is not limitative. In this example, a difference G between the third determination threshold Vt3 and the third lower limit voltage Vs3 is set to be greater than the product of the third voltage drop rate Rc and the third processing time Tc. The third determination threshold Vt3 is thus greater than a value obtained by adding the product of the third voltage drop rate Rc and the third processing time Tc to the third lower limit voltage Vs3. In this example, the third processing time Tc is a time from when the holder 62 starts decelerating (decreasing the advancing and retracting speed) to when the holder 62 stops moving in the advancement and retraction direction Y.

In the present embodiment, as shown in FIG. 8, the controller 10 determines whether the third target voltage V3 is greater than the third determination threshold Vt3 (S21). When determining that the third target voltage V3 is less than or equal to the third determination threshold Vt3 (No in S21), the controller 10 performs the third deceleration and stop process (S22). In this example, when detecting that the third target voltage V3 drops to the same as the third determination threshold Vt3, the controller 10 controls the slider 82 to decelerate the holder 62. The controller 10 controls the slider 82 to stop sliding the holder 62 before the third target voltage V3 drops below the third lower limit voltage Vs3. In the example in FIG. 5, the controller 10 stops the holder 62 in response to the third target voltage V3 being the same as the third lower limit voltage Vs3. In this manner, in the third deceleration and stop process, the controller 10 controls the slider 82 to stop the holder 62 within a period in which the third target voltage V3 is less than the third determination threshold Vt3 and greater than or equal to the third lower limit voltage Vs3. The controller 10 may transmit information about the stop position of the holder 62 in the advancement and retraction direction Y to the host control system C after the third deceleration and stop process. This allows the host control system C to estimate the accurate stop position of the holder 62 more easily in a restoration operation after the power supply failure is removed. This shortens the time taken for the restoration operation. The controller 10 can estimate the position of the holder 62 in the advancement and retraction direction Y using, for example, an encoder mounted on the slider motor. In this example, as shown in FIG. 5, the first determination threshold Vt1, the second determination threshold Vt2, and the third determination threshold Vt3 are set to the same value, but these values may be different from one another.

As shown in FIG. 5, when the first deceleration and stop process is not performed, the traveling transport vehicle 1 suddenly stops traveling in response to the first target voltage V1 being lower than or equal to the first lower limit voltage Vs1. Similarly, when the second deceleration and stop process is not performed, the lifting or lowering of the holder 62 suddenly stops in response to the second target voltage V2 being lower than or equal to the second lower limit voltage Vs2. When the third deceleration and stop process is not performed, the holder 62 suddenly stops sliding in response to the third target voltage V3 being lower than or equal to the third lower limit voltage Vs3. In the example in FIG. 5, when the normal voltage V0 is applied, the travel speed of the transport vehicle 1, the lifting and lowering speed of the holder 62, and the advancing and retracting speed of the holder 62 are each a constant speed S1. When the target voltages drop to the lower limit voltages (time T2), the travel speed of the transport vehicle 1, the lifting and lowering speed of the holder 62, and the advancing and retracting speed of the holder 62 decrease at constant deceleration rate and reach zero (time T3). FIG. 5 simply shows changes in the travel speed of the transport vehicle 1, the lifting and lowering speed of the holder 62, and the advancing and retracting speed of the holder 62 in a schematic and collective manner. Thus, the speed S1 indicating the travel speed of the transport vehicle 1, the speed S1 indicating the lifting and lowering speed of the holder 62, and the speed S1 indicating the advancing and retracting speed of the holder 62 may differ from one another.

In the example in FIG. 5, when the first deceleration and stop process is performed, the controller 10 controls the transport vehicle 1 to decelerate in response to the first target voltage V1 being lower than or equal to the first determination threshold Vt1 (time T1), and stops the transport vehicle 1 in response to the first target voltage V1 reaching the first lower limit voltage Vs1 (time T2). Similarly, when the second deceleration and stop process is performed, the controller 10 controls the lifting or lowering of the holder 62 to decelerate in response to the second target voltage V2 being lower than or equal to the second determination threshold Vt2 (time T1), and stops the lifting or lowering of the holder 62 in response to the second target voltage V2 reaching the second lower limit voltage Vs2 (time T2). When the third deceleration and stop process is performed, the controller 10 also controls the sliding movement of the holder 62 to decelerate in response to the third target voltage V3 being lower than or equal to the third determination threshold Vt3 (time T1), and stops the sliding movement of the holder 62 in response to the third target voltage V3 reaching the third lower limit voltage Vs3 (time T2). The travel speed of the transport vehicle 1, the lifting and lowering speed of the holder 62, and the advancing and retracting speed of the holder 62 decrease more gently when the first deceleration and stop process, the second deceleration and stop process, and the third deceleration and stop process are performed than when these processes are not performed. In the example in FIG. 5, the travel of the transport vehicle 1, the lifting or lowering of the holder 62, and the sliding of the holder 62 stop earlier (time T2) when the first deceleration and stop process, the second deceleration and stop process, and the third deceleration and stop process are performed than when these processes are not performed.

### Other Embodiments

(1) In the above embodiment, the transport vehicle 1 transports the article W to the multiple processing devices 7, but the structure is not limited to this example. The transport vehicle 1 may transport the article W to, for example, a storage shelf for storing articles W.

(2) In the above embodiment, each of the travel of the transport vehicle 1, the lifting or lowering of the holder 62, and the sliding of the holder 62 stops earlier when the first deceleration and stop process, the second deceleration and stop process, and the third deceleration and stop process are performed than when these processes are not performed. The structure is not limited to this example. For example, each of the travel of the transport vehicle 1, the lifting or lowering of the holder 62, and the sliding of the holder 62 may stop at the same timing when the first deceleration and stop process, the second deceleration and stop process, and the third deceleration and stop process are performed and when these processes are not performed.

(3) In the above embodiment, the first determination threshold Vt1 is a value greater than or equal to a value obtained by adding the product of the first voltage drop rate Ra and the first processing time Ta to the first lower limit voltage Vs1, but the structure is not limited to this example. The first determination threshold Vt1 may be any value greater than the first lower limit voltage Vs1 and less than the normal voltage V0.

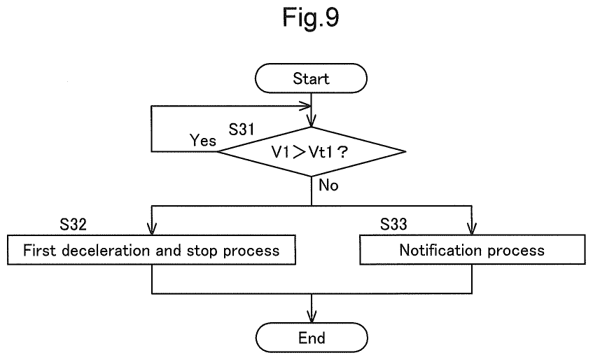

(4) In the above embodiment, the controller 10 controls, as the first deceleration and stop process, the traveler 2 to decelerate the transport vehicle 1 at a constant deceleration rate to stop the transport vehicle 1 in response to the first target voltage V1 being lower than or equal to the first determination threshold Vt1, without setting a target stop position for the transport vehicle 1. The structure is not limited to this example. In the deceleration and stop process, the controller 10 may set a target stop position and control the traveler 2 to stop the transport vehicle 1 at the target stop position, and may also perform a notification process of notifying the host control system C of the target stop position through the communication device 9. FIG. 9 shows an example of such control. As shown in FIG. 9, when determining that the first target voltage V1 is lower than or equal to the first determination threshold Vt1 (No in S31), the controller 10 performs the first deceleration and stop process (S32) and the notification process (S33). In this example, the controller 10 sets the target stop position for the transport vehicle 1 while performing the first deceleration and stop process. The target stop position may be a position forward in the travel direction X by a predetermined distance from a detectable member 43 detected the latest by the detector 15 in the transport vehicle 1. The deceleration rate for the transport vehicle 1 may be predetermined, for example, and the predetermined distance may be calculated based on the deceleration rate. The controller 10 may store map information about the travel path 5 and set the target stop position for the transport vehicle 1 using the map information. The controller 10 performs the notification process of transmitting information about the set target stop position to the host control system C when performing the first deceleration and stop process. The controller 10 may perform the notification process after starting but before completing the first deceleration and stop process. The controller 10 may notify, as the notification process, the host control system C of the position at which the transport vehicle 1 started decelerating. In this case, the target stop position is calculated by the host control system C.

(5) In the above embodiment, the power supply unit 3 includes the power storage 31 that temporarily stores power, but the structure is not limited to this example. The power supply unit 3 may not include the power storage 31.

(6) In the above embodiment, the controller 10 monitors the second target voltage V2 to perform the second deceleration and stop process, but the structure is not limited to this example. The controller 10 may not monitor the second target voltage V2. In this case, the controller 10 does not perform the second deceleration and stop process. In some embodiments, in the second deceleration and stop process, the controller 10 may control the lifter 72 to accommodate the holder 62 in the compartment 17 independently of the position of the holder 62 in response to the second target voltage V2 being lower than or equal to the second determination threshold Vt2.

(7) In the above embodiment, the controller 10 monitors the third target voltage V3 to perform the third deceleration and stop process, but the structure is not limited to this example. The controller 10 may not monitor the third target voltage V3. In this case, the controller 10 does not perform the third deceleration and stop process. In some embodiments, in the third deceleration and stop process, the controller 10 may control the lifter 72 to accommodate the holder 62 in the compartment 17 independently of the position of the holder 62 in the advancement and retraction direction Y in response to the third target voltage V3 being lower than or equal to the third determination threshold Vt3.

(8) The structure described in each of the above embodiments may be combined with any other structures described in the other embodiments unless any contradiction arises. This also applies to combinations of the embodiments described as other embodiments. For other structures as well, the embodiments described herein are merely illustrative in all aspects. Thus, the embodiments described herein may be modified variously as appropriate without departing from the spirit and scope of the disclosure.

### Overview of Embodiments

An overview of the transport vehicle described above is provided below.

A transport vehicle according to an aspect of the disclosure is a transport vehicle for transporting an article. The transport vehicle includes a traveler including a traveler driver, a controller that controls the traveler, and a power supply unit that receives power from an external source and supplies the power at least to the traveler and the controller. The controller monitors a target voltage applied by the power supply unit to the traveler. The controller performs, during travel of the transport vehicle, a deceleration and stop process of decreasing a travel speed of the transport vehicle to stop the travel of the transport vehicle in response to the target voltage being lower than or equal to a determination threshold. The determination threshold is lower than a voltage of the power supply unit in normal operation and higher than a lower limit voltage. The lower limit voltage is a minimum voltage to cause the traveler to operate.

In this structure, when a power supply failure due to, for example, a power outage or a trouble in the power supply unit causes a drop in the voltage (target voltage) applied to the traveler below the lower limit voltage, the transport vehicle can start decelerating in response to the voltage reaching the determination threshold. This structure can thus avoid a sudden stop of the transport vehicle with the traveler inoperable due to the target voltage lower than the lower limit voltage.

In this manner, the structure can avoid a sudden stop of the transport vehicle, reducing adverse effects such as a larger acceleration on the article being transported.

The determination threshold may be greater than or equal to a value obtained by adding a product of a voltage drop rate and a processing time to the lower limit voltage, where the processing time is a time from a start to a completion of the deceleration and stop process, and the voltage drop rate is a decrease in the target voltage per unit time resulting from abnormal power supply from the power supply unit.

In this structure, the deceleration and stop process can be complete within a period in which the target voltage is lower than or equal to the determination threshold but yet to reach the lower limit voltage. Thus, when the voltage applied to the traveler drops due to a power supply failure, the transport vehicle can be properly decelerated and stopped.

The transport vehicle may further include a communication device that communicates with a host control system that controls a plurality of the transport vehicles. The controller may control the traveler based on a command from the host control system. In the deceleration and stop process, the controller may set a target stop position, control the traveler to stop the transport vehicle at the target stop position, and perform a notification process of notifying the host control system of the target stop position through the communication device.

In this structure, the host control system can determine the stop position of the transport vehicle, reducing the effort in the restoration process after the power supply failure is removed.

The power supply unit may include a power storage that stores power temporarily, and applies a voltage of the power storage to the traveler.

This structure can avoid a sudden drop in the voltage applied to the traveler when a power supply failure occurs. Thus, the controller is more likely to have time to perform the deceleration and stop process.

The transport vehicle may further include a holder that holds the article, and a lifter that lifts and lowers the holder. The controller may further monitor a second target voltage applied by the power supply unit to the lifter. The controller may perform, during the holder being lifted or lowered by the lifter, a second deceleration and stop process of decreasing a speed of the holder being lifted or lowered by the lifter to stop lifting or lowering of the holder in response to the second target voltage being lower than or equal to a second determination threshold. The second determination threshold is lower than a voltage of the power supply unit in normal operation and higher than a second lower limit voltage. The second lower limit voltage is a minimum voltage to cause the lifter to operate.

In this structure, when a power supply failure due to, for example, a power outage or a trouble in the power supply unit causes a drop in the voltage (second target voltage) applied to the lifter, the speed of lifting or lowering the holder can start decreasing in response to the voltage reaching the second determination threshold. This structure can thus avoid a sudden stop of the holder with the lifter inoperable in response to the second target voltage lower than the second lower limit voltage.

In this manner, the structure can avoid a sudden stop of the holder being lifted or lowered, reducing adverse effects such as a larger acceleration on the article being lifted and lowered.

The transport vehicle may further include a holder that holds the article, and a slider that advances and retracts the holder in an advancement and retraction direction parallel to a horizontal direction. The controller may further monitor a third target voltage applied by the power supply unit to the slider. The controller may perform, during the holder being advanced or retracted by the slider, a third deceleration and stop process of decreasing a speed of the holder being advanced or retracted by the slider to stop advancing or retracting of the holder in response to the third target voltage being lower than or equal to a third determination threshold. The third determination threshold is lower than a voltage of the power supply unit in normal operation and higher than a third lower limit voltage. The third lower limit voltage is a minimum voltage to cause the slider to operate.

In this structure, when a power supply failure due to, for example, a power outage of a trouble in the power supply unit causes a drop in the voltage (third target voltage) applied to the slider, the speed of advancing or retracting the holder can start decreasing in response to the voltage reaching the third determination threshold.

This structure can thus avoid a sudden stop of the holder with the slider inoperable in response to the third target voltage lower than the third lower limit voltage.

In this manner, the structure can avoid a sudden stop of the holder being advanced or retracted, reducing adverse effects such as a larger acceleration on the article being advanced or retracted.

The transport vehicle according to one or more embodiments of the disclosure produces at least one of the effects described above.

What is claimed is:

1. A transport vehicle for transporting an article, the transport vehicle comprising:
a traveler comprising a traveler driver;
a controller configured to control the traveler; and
a power supply unit configured to receive power from an external source and supply the power at least to the traveler and the controller, and
wherein:
the controller is configured to monitor a target voltage applied by the power supply unit to the traveler,
the controller is configured to perform, during travel of the transport vehicle, a deceleration and stop process of decreasing a travel speed of the transport vehicle to stop the travel of the transport vehicle in response to the target voltage being lower than or equal to a determination threshold,
the determination threshold is lower than a voltage of the power supply unit in normal operation and higher than a lower limit voltage, and
the lower limit voltage is a minimum voltage to cause the traveler to operate.

2. The transport vehicle according to claim 1, wherein:
the determination threshold is greater than or equal to a value obtained by adding a product of a voltage drop rate and a processing time to the lower limit voltage, where the processing time is a time from a start to a completion of the deceleration and stop process, and the voltage drop rate is a decrease in the target voltage per unit time resulting from abnormal power supply from the power supply unit.

3. The transport vehicle according to claim 1, further comprising:
a communication device configured to communicate with a host control system configured to control a plurality of the transport vehicles,
wherein the controller is configured to control the traveler based on a command from the host control system, and
wherein the controller is configured to, in the deceleration and stop process, set a target stop position, control the traveler to stop the transport vehicle at the target stop position, and perform a notification process of notifying the host control system of the target stop position through the communication device.

4. The transport vehicle according to claim 1, wherein:
the power supply unit comprises a power storage configured to store power temporarily, and applies a voltage of the power storage to the traveler.

5. The transport vehicle according to claim 1, further comprising:
a holder configured to hold the article; and
a lifter configured to lift and lower the holder, and
wherein:
the controller is configured to further monitor a second target voltage applied by the power supply unit to the lifter,
the controller is configured to perform, during the holder being lifted or lowered by the lifter, a second deceleration and stop process of decreasing a speed of the holder being lifted or lowered by the lifter to stop lifting or lowering of the holder in response to the second target voltage being lower than or equal to a second determination threshold,
the second determination threshold is lower than a voltage of the power supply unit in normal operation and higher than a second lower limit voltage, and
the second lower limit voltage is a minimum voltage to cause the lifter to operate.

6. The transport vehicle according to claim 1, further comprising:
a holder configured to hold the article; and
a slider configured to advance and retract the holder in an advancement and retraction direction parallel to a horizontal direction, and
wherein:
the controller is configured to further monitor a third target voltage applied by the power supply unit to the slider,
the controller is configured to perform, during the holder being advanced or retracted by the slider, a third deceleration and stop process of decreasing a speed of the holder being advanced or retracted by the slider to stop advancing or retracting of the holder in response to the third target voltage being lower than or equal to a third determination threshold,
the third determination threshold is lower than a voltage of the power supply unit in normal operation and higher than a third lower limit voltage, and
the third lower limit voltage is a minimum voltage to cause the slider to operate.
